(19) United States
(12) Patent Application Publication
(10) Pub. No.: US 2024/0332264 A1
(43) Pub. Date: Oct. 3, 2024

(54) PIXEL PACKAGE

(71) Applicant: EPISTAR CORPORATION, Hsinchu (TW)

(72) Inventors: Min-Hsun HSIEH, Hsinchu (TW); Kun-Wei KAO, Hsinchu (TW); Teng-Hui HSIEH, Hsinchu (TW)

(21) Appl. No.: 18/615,912

(22) Filed: Mar. 25, 2024

(30) Foreign Application Priority Data
Mar. 31, 2023 (TW) 112112399

(51) Int. Cl. H01L 25/075; H01L 33/62

(52) U.S. Cl. CPC H01L 25/0753; H01L 33/62

(57) ABSTRACT

A pixel package includes a first light-emitting diode, a second light-emitting diode, a third light-emitting diode, a transparent layered structure, and a first conductive structure. The first light-emitting diode has a first light-emitting surface and a first bottom surface opposite thereto, and the first light-emitting diode is arranged side by side with the second light-emitting diode over the first light-emitting surface. The transparent layered structure encapsulates and separates the first light-emitting diode, the second light-emitting diode, and the third light-emitting diode. The first conductive structure has a first portion and a second portion. The first portion is located between the first light-emitting diode and the first light-emitting surface. The second portion is located under the first portion and is exposed from the transparent layered structure. In a plan view, the third light-emitting diode is respectively overlapped with the first light-emitting diode and the second light-emitting diode.

### CROSS-REFERENCE TO RELATED APPLICATIONS

This application claims priority to, and the benefit of, Taiwan Patent Application Number 112112399 filed on Mar. 31, 2023, the entire content of which is hereby incorporated by reference herein in its entirety.

### TECHNICAL FIELD

The present disclosure relates to a pixel package, and more particularly, to a pixel package with vertically stacked light-emitting diodes.

### DESCRIPTION OF BACKGROUND ART

The light-emitting diode (LED) has many advantages such as low power consumption, low heat generation, long operating life, high impact resistance, small size, and fast reaction speed. It is widely used in a variety of fields that require the use of luminescent components, such as vehicles, appliances, display installations and lighting fixtures. Furthermore, the light emitted by the light-emitting diodes belongs to a monochromatic light and is therefore suitable for use in the display installations. For example, as a sub-pixel for outdoor or indoor display installations.

In order to improve the resolution of the display screens, reducing the size of light-emitting diodes in the display installation becomes the future development direction.

### SUMMARY OF THE APPLICATION

According to one embodiment of the present disclosure, a pixel package is disclosed. The pixel package includes a first light-emitting diode, a second light-emitting diode, a third light-emitting diode, a transparent layered structure, and a first conductive structure. The third light-emitting diode has a first light-emitting surface and a first bottom surface opposite to the first light-emitting surface, and the first light-emitting diode is arranged side by side with the second light-emitting diode over the third light-emitting surface. The transparent layered structure encapsulates and separates the first light-emitting diode, the second light-emitting diode, and the third light-emitting diode. The first conductive structure has a first portion and a second portion. The first portion is located between the first light-emitting diode and the first light-emitting surface. The second portion is located under the first portion and is exposed from the transparent layer. In a plan view, the third light-emitting diode is respectively overlapped with the first light-emitting diode and the second light-emitting diode.

### BRIEF DESCRIPTION OF THE DRAWINGS

The embodiments of the present disclosure may be more fully understood by reading the subsequent detailed description and examples with references made to the accompanying drawings. In addition, for clarity, the features in the drawings may not be drawn to actual scale, so some features in some drawings may be deliberately enlarged or reduced in size, wherein:

FIG. 1A illustrates a top view of a pixel package in accordance with one embodiment of the present disclosure.

FIG. 1B illustrates a cross-sectional view of a pixel package in accordance with one embodiment of the present disclosure.

FIG. 1C illustrates another cross-sectional view of a pixel package in accordance with one embodiment of the present disclosure.

FIGS. 2A, 3A, 4A, 5A, 6A, 7A, 8A, 9A, 10A, 11A, 12A illustrate three-dimensional schematic diagrams of the intermediate stages of forming a pixel package in accordance with one embodiment of the present disclosure.

FIGS. 2B, 3B, 4B, 5B, 6B, 7B, 8B, 9B, 10B, 11B, 12B illustrate cross-sectional views along lines A-A′ in FIGS. 2A, 3A, 4A, 5A, 6A, 7A, 8A, 9A, 10A, 11A, 12A, which are cross-sectional views of work in process (WIP).

FIGS. 13-16 illustrate cross-sectional views of forming the works in process of a pixel package in accordance with another embodiment of the present disclosure.

### DETAILED DESCRIPTION OF THE APPLICATION

The pixel packages and manufacturing methods thereof in accordance with the embodiments of the present disclosure are described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. The embodiments are used merely for the purpose of illustration. In addition, the drawings of different embodiments may use like and/or corresponding numerals to denote like and/or corresponding elements in order to clearly describe the present disclosure. However, the use of like and/or corresponding numerals in the drawings of different embodiments does not suggest any correlation between different embodiments.

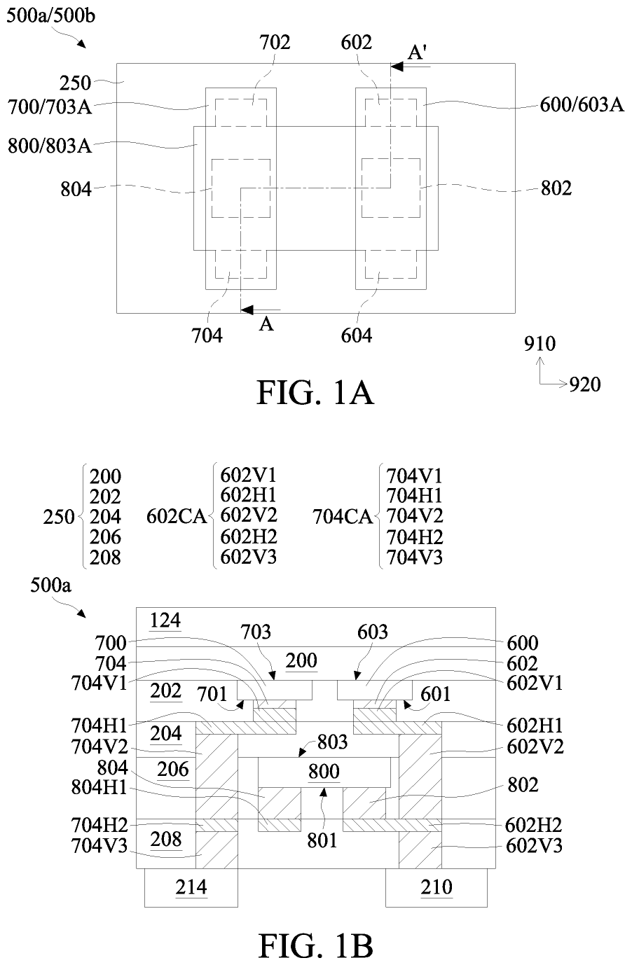

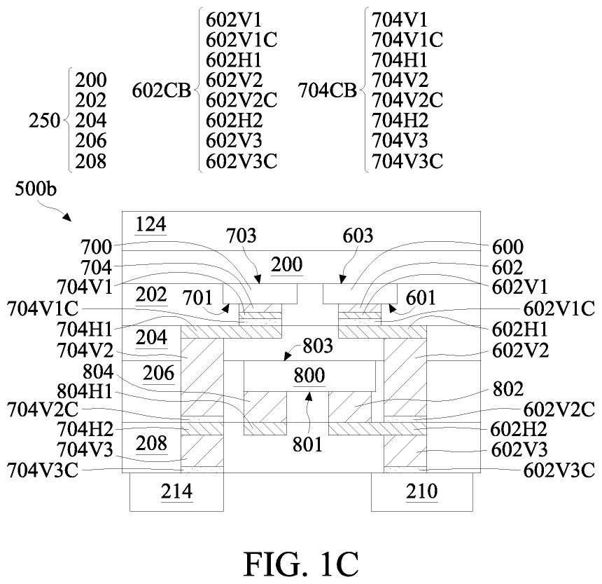

FIG. 1A illustrates a top view of a pixel package 500a/500b in accordance with some embodiments of the present disclosure. A first light-emitting diode 600, a second light-emitting diode 700, and a third light-emitting diode 800 are encapsulated in a transparent layered structure 250. FIG. 1B is a cross-sectional view along line A-A′ of FIG. 1A. The first light-emitting diode 600 and the second light-emitting diode 700 are superimposed on the third light-emitting diode 800. For clarity, FIG. 1A shows only the transparent layered structure 250, the first light-emitting diode 600, the second light-emitting diode 700, the third light-emitting diode 800, the first electrodes 602, 702, 802, and the second electrodes 604, 704, 804, and while the rest of the components may be referenced to FIG. 1B.

As shown in FIG. 1B, the pixel package body 500a includes a first light-emitting diode 600, a second light-emitting diode 700, a third light-emitting diode 800, a transparent layered structure 250, a first conductive structure 602CA, a third conductive structure 704CA, and a redistribution layer (RDL) 804H1. Each of the first light-emitting diodes 600, the second light-emitting diode 700, and the third light-emitting diode 800 has a light-emitting surface 603, 703, 803 and a bottom surface 601, 701, 801 opposite to the corresponding light-emitting surface 603, 703, 803, respectively. Moreover, each of the first light-emitting diode 600, the second light-emitting diode 700, and the third light-emitting diode 800 respectively has a first electrode 602, 702 (not shown), 802 and a second electrode 604 (not shown), 704, 804 separated from each other, and the second electrodes are arranged on the bottom surfaces 601, 701, 801 which are away from the corresponding light-emitting surfaces 603, 703 and 803. The first electrodes 602, 702, 802 and the second electrodes 604, 704, 804 have different polarities. For example, the first electrodes 602, 702, 802 are cathodes, and the second electrodes 604, 704, 804 are anodes. The first light-emitting diode 600 and the second light-emitting diode 700 are arranged side by side above the light-emitting surface 803 of the third light-emitting diode 800. In addition, the light-emitting surface 803 of the third light-emitting diode 800 is near the bottom surface 601 of the first light-emitting diode 600 and the bottom surface 701 of the second light-emitting diode 700.

As shown in FIG. 1A, the third light-emitting diode 800 is overlapped with the first light-emitting diode 600 and the second light-emitting diode 700. In more detail, the long sides of the first light-emitting diode 600 and the second light-emitting diode 700 are along a same direction 910 and are perpendicular to the long side of the third light-emitting diode 800 (extending along direction 920). In addition, the light-emitting surface 603 of the first light-emitting diode 600 has a surface area of 603A, the light-emitting surface 703 of the second light-emitting diode 700 has a surface area of 703A, and the light-emitting surface 803 of the third light-emitting diode 800 has a surface area of 803A. In some embodiments, both the surface areas 603A and the surface area 703A are smaller than the surface area 803A. In one embodiment, the first light-emitting diode 600 is a blue light-emitting diode chip, the second light-emitting diode 700 is a green light-emitting diode chip, and the third light-emitting diode 800 is a red light-emitting diode chip. Because the red light-emitting diode chip is more susceptible to the sidewall defect effect that may affect its luminous efficiency, the third light-emitting diode 800 has a larger surface area 803A than the surface area 603A and the surface area 703A, so the three light-emitting diodes are able to emit light of similar intensity.

In some embodiments, the first light-emitting diode 600, the second light-emitting diode 700, and the third light-emitting diode 800 are flip-chip light-emitting diodes, which may be thin film flip-chip light-emitting diodes without growth substrates. In some embodiments, the first light-emitting diode 600 can emit a first-color light, the second light-emitting diode 700 can emit a second-color light, and the third light-emitting diode 800 can emit a third-color light. The first-color light, the second-color light, and the third-color light respectively have a different dominant wavelength. For example, the first light-emitting diode 600 emits a blue light, the second light-emitting diode 700 emits a green light, and the third light-emitting diode 800 emits a red light.

As shown in FIGS. 1A and 1B, in the pixel package 500a, the transparent layered structure 250 encapsulates and separates the first light-emitting diode 600, the second light-emitting diode 700, and the third light-emitting diode 800. The transparent layered structure 250 includes a laminated structure formed by stacking multiple transparent sublayers 200, 202, 204, 206, and 208. Wherein, the transparent sublayers 200 and 202 encapsulate the first light-emitting diode 600 and the second light-emitting diode 700, and the transparent sublayers 204 and 206 encapsulate the third light-emitting diode 800. The transparent sublayers 200, 202, 204, 206 are able to provide support for the first light-emitting diode 600, the second light-emitting diode 700, and the third light-emitting diode 800, and may serve as an electrical insulating layer between any two of the first light-emitting diode 600, the second light-emitting diode 700, and the third light-emitting diode 800. In addition, the transparent layered structure 250 may also contain a redistribution layer to electrically connect the first light-emitting diode 600, the second light-emitting diode 700, and the third light-emitting diode 800 to the external circuit (not shown). In addition, the transparent layered structure 250 may be penetrated by the first-color, the second-color, and the third-color lights emitted by the first light-emitting diode 600, the second light-emitting diode 700, and the third light-emitting diode 800. For example, the transparent layered structure 250 has a light transmittance greater than 50%, 60%, 70%, 80%, or 90% of the transmittance for the first-color, second-color, and third-color lights. The quantity of the transparent sublayers shown in FIG. 1B is for illustrative purpose only and not intended to limit the scope of this disclosure. In one embodiment, the material of the transparent layered structure 250 includes a photoimageable dielectric material (PID). In another embodiment, the material of the transparent layer 250 includes epoxy resin (EPO), silicone, polyimide (PI), benzocyclobutene (BCB), polybenzoxazole (PBO), or a combination of the above-mentioned materials. In some embodiments, the transparent layered structure 250 is formed by using a spin coating process.

As shown in FIG. 1B, the pixel package 500a further includes a carrier 124 positioned above the transparent layered structure 250 and the light-emitting surfaces 603, 703 and 803 of the first light-emitting diode 600, the second light-emitting diode 700, and the third light-emitting diode 800. The carrier 124 is able to carry the transparent layered structure 250, the first light-emitting diode 600, the second light-emitting diode 700, and the third light-emitting diode 800, which is beneficial to maintain a higher structural stability of the pixel package 500A during the transfer process. In addition, the carrier 124 may be penetrated by the first-color, second-color, and third-color lights emitted by the first light-emitting diode 600, the second light-emitting diode 700, and the third light-emitting diode 800. For example, the transparent layer 250 has a light transmittance greater than 50%, 60%, 70%, 80%, or 90% of the transmittance for the first-color, second-color, and third-color lights. In one embodiment, the transparent layered structure 250 and the carrier 124 are both made of the same material. For example, an organic polymer material. In addition, the transparent layered structure 250 and the carrier 124 may also be made of different materials. In one embodiment, the hardness of the carrier 124 may be higher than the hardness of the transparent layered structure 250 to withstand the impact of the outside shock. The material of the carrier 124 includes polymethyl methacrylate (PMMA), acrylonitrile butadiene styrene (ABS), polyamide (PA), polycarbonate (PC), polyethylene (PE), polyoxymethylene (POM), polypropylene (PP), polystyrene (PS), epoxy resin (EPO), silicone, or a combination of the above-mentioned materials. In one embodiment, the carrier 124 is formed by transfer molding, spin coating, and so on.

As shown in FIG. 1B, the first conductive structure 602CA is formed in the transparent layered structure 250 and connected to the first electrode 602 of the first light-emitting diode 600, the second electrode 702 (not shown) of the second light-emitting diode 700, and the third electrode 802 of the third light-emitting diode 800. When the first electrodes 602, 702, and 802 are cathodes, the first conductive structure 602CA may be regarded as a common cathode conductive structure. The first conductive structure 602CA includes a conductive through hole (via) 602V1 in the transparent sublayer 202, a redistribution layer 602H1 in the transparent sublayer 204, a conductive through hole 602V2 in the transparent sublayers 204 and 206, and a redistribution layer 602H2 and a conductive through hole 602V3 in the transparent sublayer 208. In some embodiments, the first conductive structure 602CA includes the connected first part (including the conductive through hole 602V1 and the redistribution layer 602H1) and second part (including the conductive through hole 602V2, the redistribution layer 602H2, and the conductive through hole 602V3). The first part of the first conductive structure 602CA is located between the first light-emitting diode 600 and the light-emitting surface 803 of the third light-emitting diode 800, and the second part of the first conductive structure 602CA is located below the first part and extends so that the bottom surface of the conductive through hole 602V3 is exposed beyond the transparent layered structure 250. Furthermore, as shown in FIG. 1B, the first part of the first conductive structure 602CA is overlapped with the light-emitting surface 803 of the third light-emitting diode 800.

The third conductive structure 704CA is formed in the transparent layered structure 250 and includes a conductive through hole 704V1 in the transparent sublayer 202, a redistribution layer 704H1 in the transparent sublayer 204, a conductive through hole 704V2 in the transparent sublayers 204 and 206, and a redistribution layer 704H2 and a conductive through hole 704V3 in the transparent sublayer 208. In one embodiment, the third conductive structure 704CA includes the connected third part (including the conductive through hole 704V1 and the redistribution layer 704H1) and fourth part (including the conductive through hole 704V2, the redistribution through layer 704H2, and the conductive through hole 704V3). The third part of the second conductive structure 704CA is located between the second light-emitting diode 700 and the light-emitting surface 803 of the third light-emitting diode 800, and the fourth part of the second conductive structure 704CA is located below the third part and extends so that the bottom surface of the conductive through hole 704V3 is exposed beyond the transparent layered structure 250. Furthermore, as shown in FIG. 1B, the third part of the second conductive structure 704CA is overlapped with the light-emitting surface 803 of the third light-emitting diode 800.

Still referring to FIG. 1B, the pixel package 500a further includes a redistribution layer 804H1 located in the transparent sublayer 208, located under the bottom surface 801 of the third light-emitting diode 800, and connected to a second electrode 804 of the third light-emitting diode 800. The configuration of the redistribution layer 804H1 in the package is described in more detail in the subsequent paragraphs.

FIG. 1C illustrates a cross-sectional view of a pixel package 500b in accordance with another embodiment of the present disclosure. The same or similar components are represented by the same or similar component symbols as those in FIGS. 1A and 1B. As shown in FIG. 1C, compared with the pixel package 500a, the first conductive structure 602CB of the pixel package 500b further includes conductive capping layers 602V1C, 602V2C, and 602V3C, and the second conductive structures 704CB of the pixel package 500b also include conductive capping layers 704V1C, 704V2C, and 704V3C. When the nano conductive glue material fills the conductive through holes, the arrangement of the conductive capping layers 602V1C, 602V2C, 602V3C, 704V1C, 704V2C, 704V2C, and 704V3C covering the corresponding conductive through holes 602V1, 602V2, 602 V3, 704V1, 704 V2 and 704V3, which may avoid the displacement of the nano conductive particles in the conductive through holes to the undesired positions in the subsequent manufacturing process which may cause a short circuit. In some embodiments, the conductive capping layers 602V1C, 602V2C, 602V3C, 704V1C, 704V2C, 704V3C are made of conductive materials such as tin.

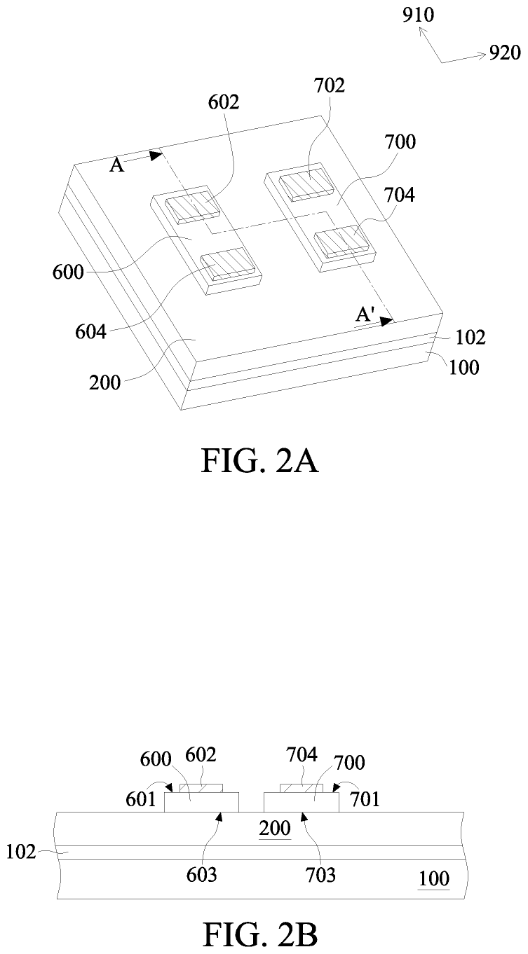

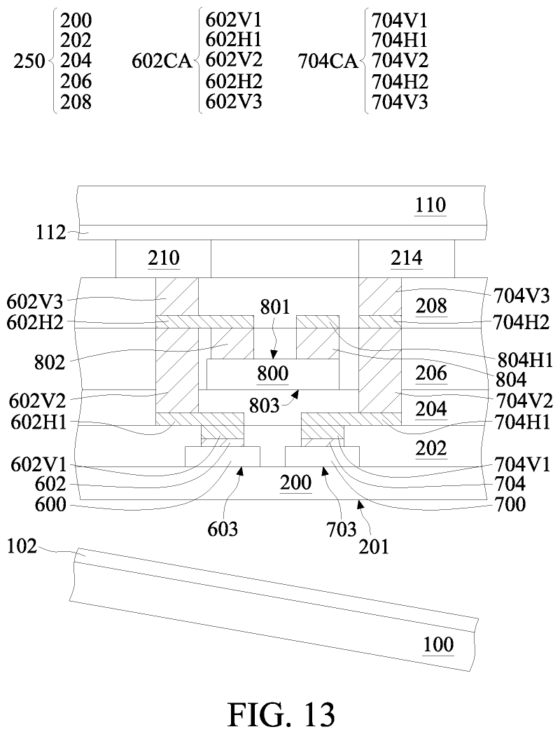

FIGS. 2A, 3A, 4A, 5A, 6A, 7A, 8A, 9A, 10A, 11A, 12A illustrate top views of the intermediate stages of forming the pixel package 500a in accordance the aforementioned embodiment of the present disclosure. FIGS. 2B, 3B, 4B, 5B, 6B, 7B, 8B, 9B, 10B, 11B, 12B illustrate cross-sectional views of the intermediate stages of forming the pixel package 500a along lines A-A′ in FIGS. 2A, 3A, 4A, 5A, 6A, 7A, 8A, 9A, 10A, 11A, 12A. FIGS. 13-16 illustrate cross-sectional views of forming the works in process of the pixel package 500a in accordance with the aforementioned embodiment of the present disclosure. The same or similar components are represented by the same or similar component symbols as those in FIGS. 1A, 1B, and 1C.

As shown in FIGS. 2A and 2B, first, provide a first carrying substrate 100 with an adhesive layer 102 thereon. Then, a transparent sublayer 200 is formed on the adhesive layer 102. Then, a transfer process (such as a laser transfer process and a stamp transfer process) is carried out to arrange the first light-emitting diode 600 and the second light-emitting diode 700 side by side on the transparent sublayer 200 so that the light-emitting surfaces 603 and 703 of the first light-emitting diode 600 and the second light-emitting diode 700 are substantially coplanar. The first electrodes 602 and 702 and the second electrodes 604 and 704 of the first light-emitting diode 600 and the second light-emitting diode 700 are respectively located under the bottom surfaces 601 and 701 and away from the transparent sublayer 200. The quantities of the first light-emitting diode 600 and the second light-emitting diode 700 arranged on the transparent sublayer 200 shown in FIGS. 2A and 2B are for illustrative purpose only and not intended to limit the scope of this disclosure. In other embodiments, a plurality of first light-emitting diodes 600 and a plurality of second light-emitting diodes 700 may be sequentially arranged in accordance with the design requirements. In some embodiments, the first carrying substrate 100 includes a sapphire substrate. In some embodiments, the adhesive layer 102 includes a material that is adhesive and easy to be dissociated in the subsequent laser lift-off (LLO) process, such as a material with the matrix includes polyimide (PI) and epoxy resin (Epoxy).

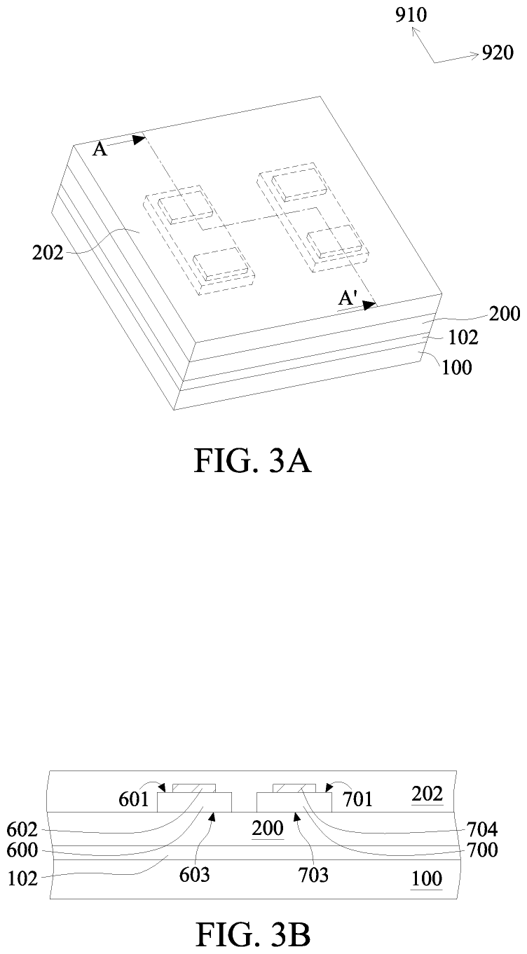

As shown in FIGS. 3A and 3B, a coating process is carried out to comprehensively form the transparent sublayer 202 on top of the transparent sublayer 200. The transparent sublayers 200 and 202 completely encloses the first light-emitting diode 600 and the second light-emitting diode 700 and covers the first electrodes 602 and 702 and the second electrodes 604 and 704. The transparent sublayer 202 can reduce the height difference between the first light-emitting diode 600, the second light-emitting diode 700 and the transparent sublayer 200. Therefore, the top surface of the transparent sublayer 202 is substantially flat.

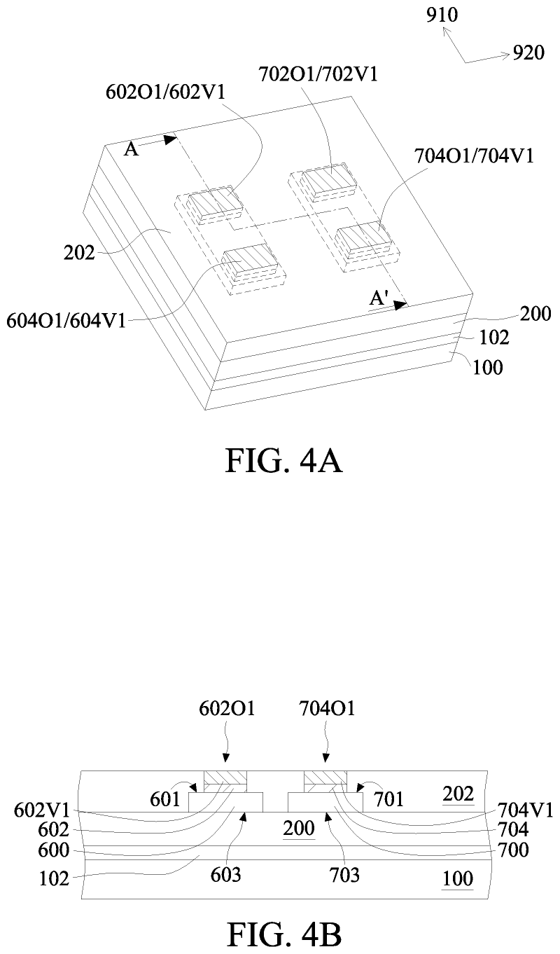

As shown in FIGS. 4A and 4B, a patterning process is carried out to form through holes 602O1, 604O1, 702O1 and 704O1 in the transparent sublayer 202 in order to expose the first electrode 602 and the second electrode 604 (FIGS. 2A and 2B) of the first light-emitting diode 600 and the first electrode 702 and the second electrode 704 (FIGS. 2A and 2B) of the second light-emitting diode 700, respectively. Then, a plating process (e.g., sputtering, electroplating, evaporation, and chemical plating) and a subsequent planarization process (e.g., chemical mechanical grinding (CMP)) are carried out in the through holes to form conductive through holes 602V1, 604V1, 702 V1, 704V1 in the through holes 602O1, 604O1, 702O1, and 704O1, respectively.

In another embodiment, conductive through holes 602V1, 604V1, 702 V1, and 704V1 may be formed by a conductive glue filling process and a subsequent heating process. In some embodiments, conductive glue includes conductive metal particles such as gold, silver, and copper, and the conductive metal particles are coated with a polymer material in the form of a paste. In more detail, conductive glue (not shown) may be filled in the through holes 602O1, 604O1, 702O1, and 704O1. After that, the heating process is carried out to volatilize the polymer material in the conductive glue, and the plurality of conductive material particles in the conductive glue are bonded together and contact with the first electrodes 602 and 702 (FIGS. 2A and 2B) and the second electrodes 604 (FIGS. 2A and 2B) and 704. In some embodiments, the temperature can be in a range of the heating process may be from 70° C. to 120° C., and can be 90° C., for example. In the embodiment of the pixel package 500b, the plating process may be carried out before heating the conductive glue to form the conductive capping layers on the top surfaces of the conductive through holes 602V1, 604V1, 702 V1, and 704V1 (e.g., conductive capping layers 602V1C, and 704V1C shown in FIG. 1C).

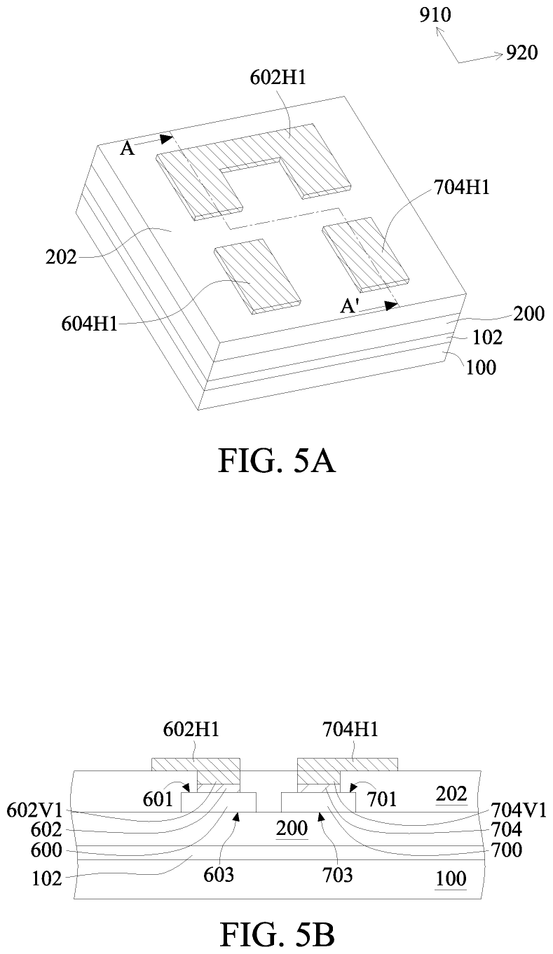

As shown in FIGS. 5A and 5B, plating and patterning processes for the redistribution layer are then carried out. In other words, the redistribution layers 602H1, 604H1, and 704H1 separated from each other are formed by a photolithography process on the transparent sublayer 202. The redistribution layer 602H1 is electrically connected to the first electrodes 602 and 702 (FIGS. 2A and 2B) of the first light-emitting diode 600 and the second light-emitting diode 700 by the conductive through holes 602V1 and 702V1 (FIGS. 4A and 4B). The redistribution layer 604H1 is electrically connected to the second electrode 604 (FIGS. 2A and 2B) of the first light-emitting diode 600 through the conductive through hole 604V1 (FIGS. 4A and 4B). The redistribution layer 704H1 is electrically connected to the second electrode 704 of the second light-emitting diode 700 through the conductive through hole 704V1.

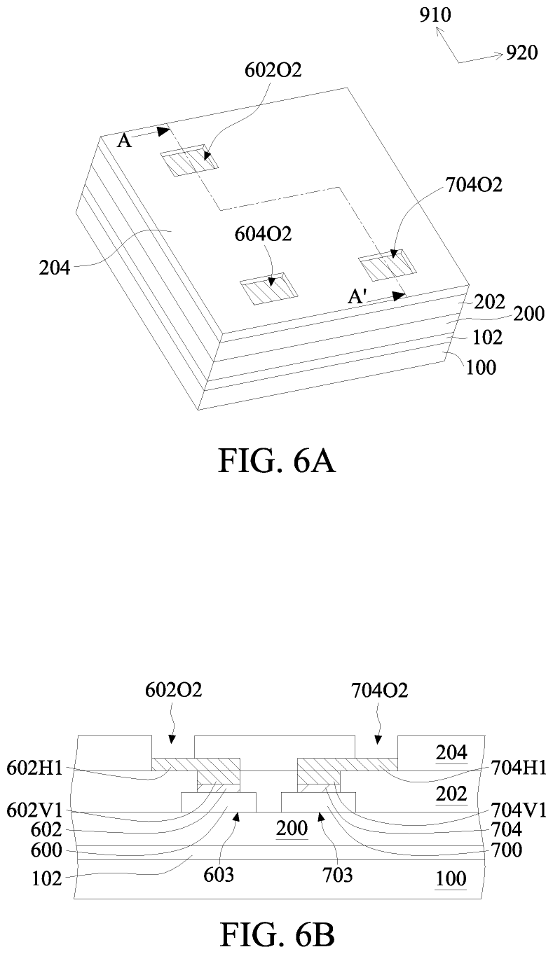

As shown in FIGS. 6A and 6B, a coating process is carried out to comprehensively form a transparent sublayer 204 on top of the redistribution layers 602H1, 604H1, and 704H1 (FIGS. 5A and 5B). The transparent sublayer 204 can reduce the height difference respectively between the redistribution layers 602H1, 604H1, 704H1 (FIGS. 5A and 5B) and the transparent sublayer 202. Therefore, the top surface of the transparent sublayer 204 is substantially flat. Then, the patterning process is carried out to form the through holes 602O2, 604O2, and 704O2 in the transparent sublayer 204, and to partially expose the redistribution layers 602H1, 604H1, and 704H1 (FIGS. 5A and 5B), respectively. In some embodiments, through holes 602O2, 604O2, and 704O2 are respectively near different corners of the pixel package 500a.

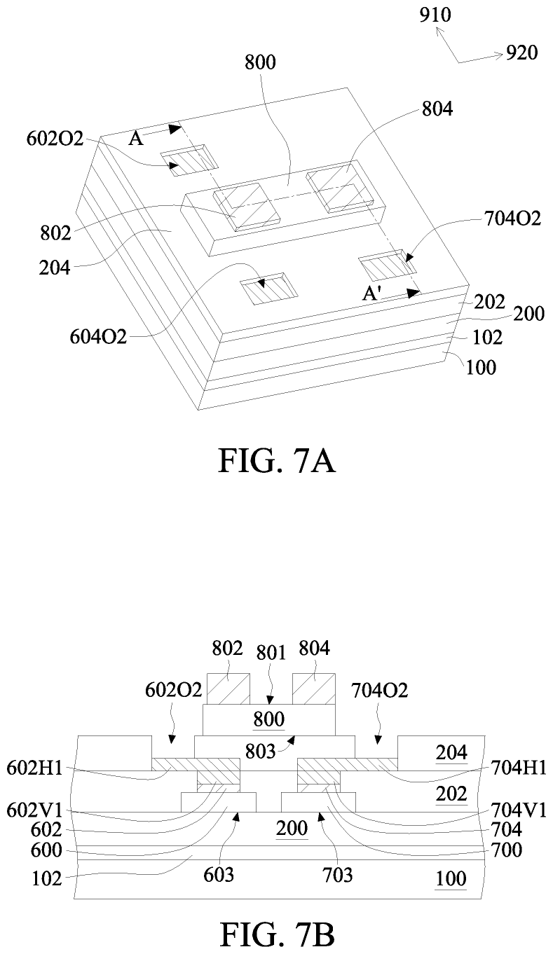

As shown in FIGS. 7A and 7B, a transfer process (e.g., a laser transfer process and a stamp transfer process) is carried out to arrange a third light-emitting diode 800 on the transparent sublayer 204. The third light-emitting diode 800 is located between the through hole 602O2 and the through holes 604O2 and 704O2, and the long side of the third light-emitting diode 800 (extending along the direction 920) is perpendicular to the long sides of the first light-emitting diode 600 and the second light-emitting diode 700 (extending along the direction 910). The light-emitting surface 803 of the third light-emitting diode 800 contacts the transparent sublayer 204, and the first electrode 802 and the second electrode 804 of the third light-emitting diode 800 are located under the bottom surface 801 and away from the transparent sublayer 204. The quantity of the third light-emitting diodes 800 arranged on the transparent sublayer 204 shown in FIGS. 7A and 7B is illustrative purpose only and not intended to limit the scope of this disclosure. In other embodiments, the quantity of the third light-emitting diode 800 is greater than one.

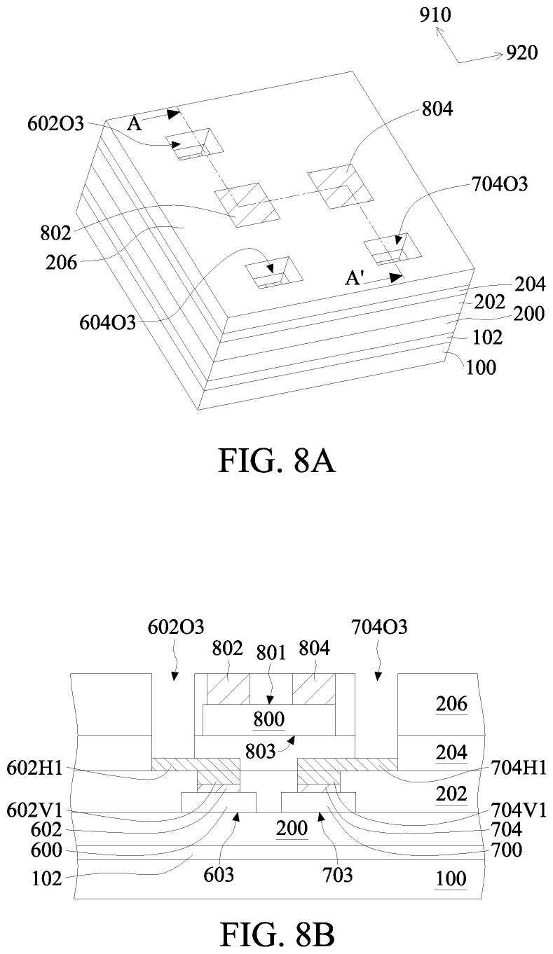

As shown in FIGS. 8A and 8B, a process similar to that shown in FIGS. 6A and 6B is carried out to form a transparent sublayer 206 surrounding the third light-emitting diode 800 on the transparent sublayer 204. The transparent sublayer 206 can reduce the height difference between the third light-emitting diode 800 and the transparent sublayer 204, and to expose the first electrode 802 and the second electrode 804 of the third light-emitting diode 800. Therefore, the top surface of the transparent sublayer 206 is substantially flat. Then, through holes 602O3, 604O3, and 704O3 penetrating through the transparent sublayer 206 are formed directly above the through holes 602O2, 604O2, and 704O2 (FIGS. 7A and 7B) by the patterning process. Through holes 602O3, 604O3, and 704O3 expose part of the redistribution layers 602H1, 604H1 (FIGS. 5A and 5B), and 704H1, respectively, and are near different corners of the pixel package 500a, respectively.

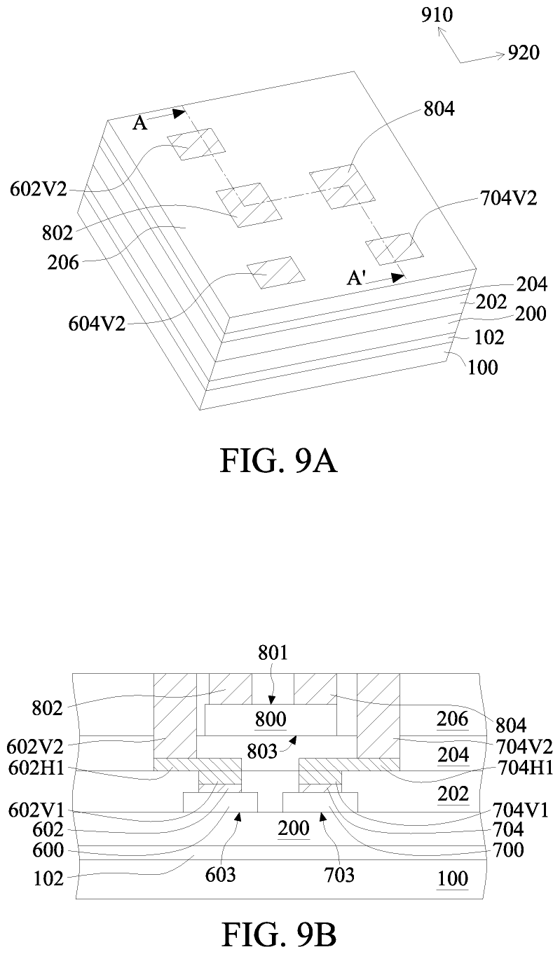

As shown in FIGS. 9A and 9B, the plating process similar to that shown in FIGS. 4A and 4B and the subsequent planarization process (or the conductive glue filling process and the subsequent heating process) are carried out to form conductive through holes 602V2, 604V2, and 704V2 in the through holes 602O3, 604O3, and 704O3 (FIGS. 8A and 8B), respectively. In the embodiment of the pixel package 500b, conductive capping layers may be formed on the top surfaces of the conductive through holes 602V2, 604V2, and 704V2 (e.g., the conductive capping layers 602V2C, and 704V2C shown in FIG. 1C).

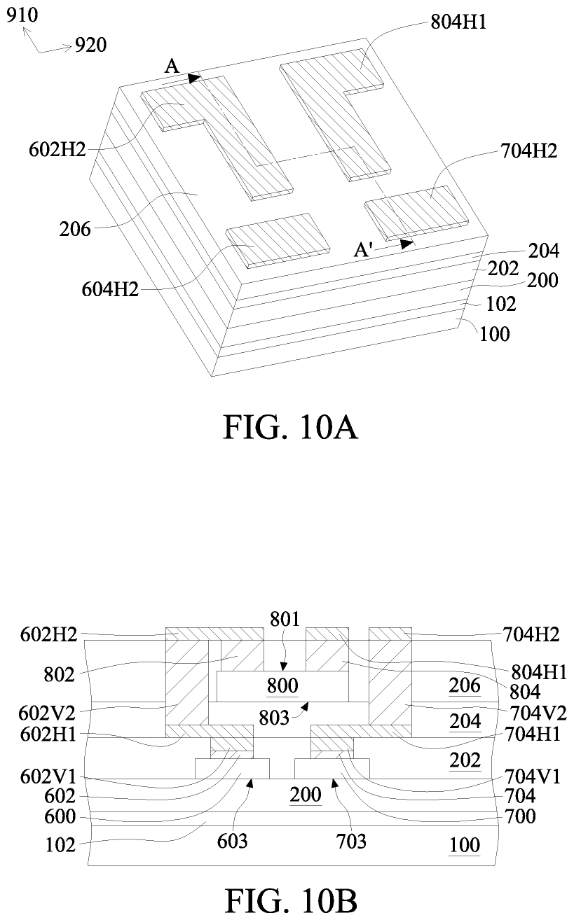

As shown in FIGS. 10A and 10B, a process similar to that shown in FIGS. 5A and 5B is carried out to form separate redistribution layers 602H2, 604H2, 704H2, and 804H1 on the transparent sublayer 206. The redistribution layer 602H2 is connected to the conductive through hole 602V2 with the first electrode 802 of the third light-emitting diode 800. The redistribution layer 604H2 is connected to the conductive through hole 604V2 (FIGS. 9A and 9B). The redistribution layer 704H2 is connected to the conductive through hole 704V2. The redistribution layer 804H1 is connected to the second electrode 804 of the third light-emitting diode 800. In some embodiments, the redistribution layers 602H2, 604H2, 704H2, and 804H1 extend to the four corners of the pixel package 500a, respectively.

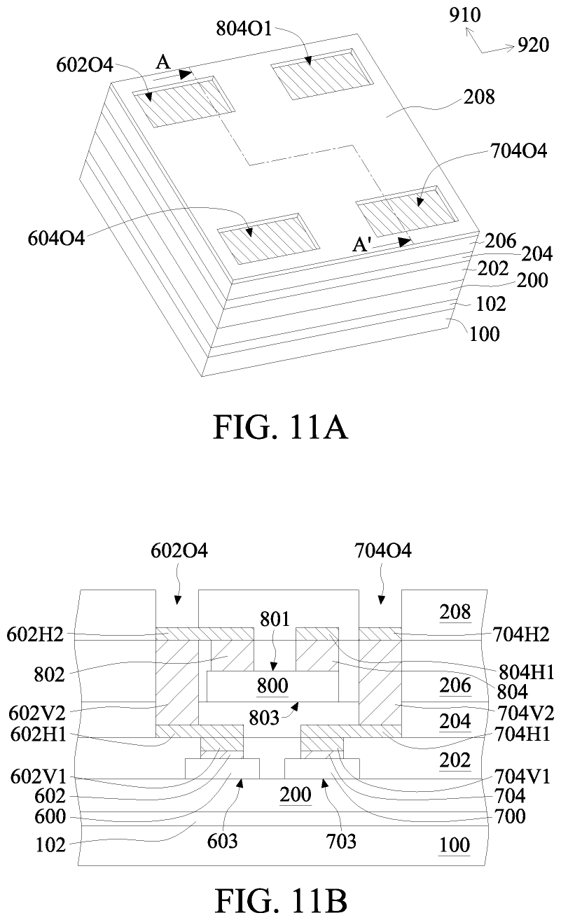

As shown in FIGS. 11A and 11B, a process similar to that shown in FIGS. 6A and 6B is carried out to form a transparent sublayer 208 covering the redistribution layers 602H2, 604H2 (FIGS. 10A and 10B), 704H2, and 804H1 (FIGS. 10A and 10B) on the transparent sublayer 206. The transparent sublayer 208 can reduce the height difference between the redistribution layers 602H2, 604H2, 704H2, 804H1, and the transparent sublayer 206 respectively.

Therefore, the top surface of the transparent sublayer 208 is a substantially flat surface. After that, through holes 602O4, 604O4, 704O4, and 804O1 are formed in the transparent sublayer 208, respectively. Through holes 602O4, 604O4, 704O4, and 804O1 expose part of the redistribution layers 602H2, 604H2, 704H2, and 804H1, respectively, and are near the four corners of the pixel package 500a.

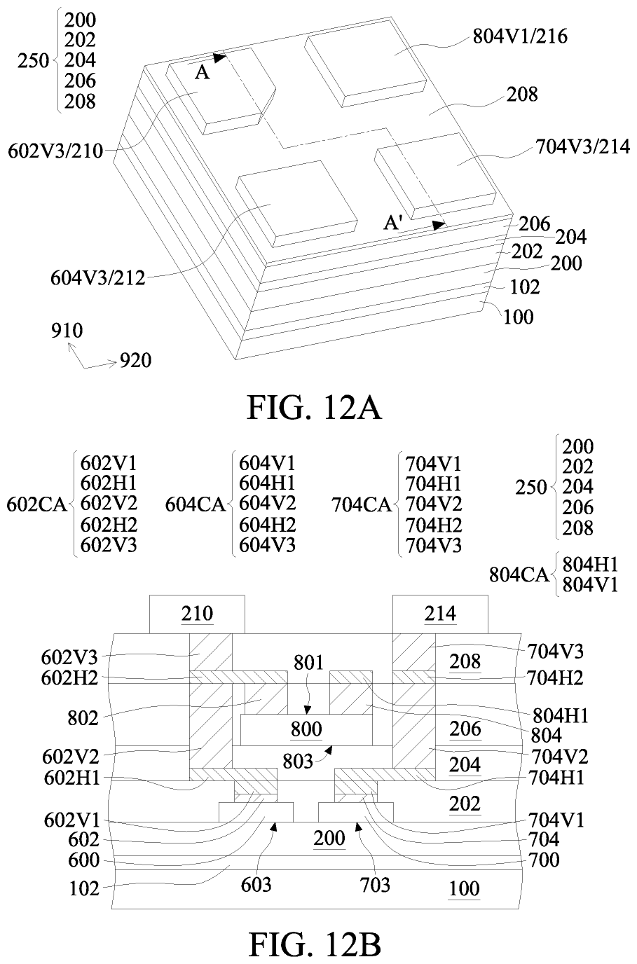

As shown in FIGS. 12A and 12B, the plating process similar to that shown in FIGS. 4A and 4B and the subsequent planarization process (or the adhesive glue filling process and the subsequent heating process) are carried out to form conductive through holes 602V3, 604V3, 704V3, and 804V1 in the through holes 602O4, 604O4, 704O4, and 804O1 (FIGS. 11A and 11B), respectively. In the embodiment of the pixel package 500b, conductive capping layers may be formed on the top surfaces of conductive through holes 602V3, 604V3, 704 V3, and 804V1 (e.g., conductive capping layers 602V3C and 704V3C shown in FIG. 1C). After finishing the above processes, the first conductive structure 602CA, the second conductive structure 604CA (described in the subsequent paragraphs), the third conductive structure 704CA, and the fourth conductive structure 804CA are formed.

Then, the plating process and the subsequent patterning process are carried out to form a first conductive pad 210, a second conductive pad 212, a third conductive pad 214, and a fourth conductive pad 216 on the transparent sublayer 208 which are separated from each other. The first conductive pad 210 is connected to the conductive through hole 602V3 of the first conductive structure 602CA. The second conductive pad 212 is connected to the conductive through hole 604V3 of the second conductive structure 604CA. The third conductive pad 214 is connected to the conductive through hole 704V3 of the third conductive structure 704CA. The fourth conductive pad 216 is connected to the conductive through hole 804V1 of the fourth conductive structure 804CA.

As shown in FIG. 12A, the first conductive pad 210, the second conductive pad 212, the third conductive pad 214, and the fourth conductive pad 216 may electrically connect the first light-emitting diode 600, the second light-emitting diode 700, and the third light-emitting diode 800 with an external circuit (not shown). The first light-emitting diode 600, the second light-emitting diode 700, and the third light-emitting diode 800 may be independently controlled to make the pixel package 500A emit a desired color light. In an embodiment, one of the first conductive pad 210, the second conductive pad 212, the third conductive pad 214, and the fourth conductive pad 216 has a shape different from the other conductive pads, so as to facilitate distinguishing the orientation of the common cathode conductive pad and the anode conductive pads of the light-emitting diode or of the entire pixel package. In one embodiment, the first light-emitting diode 600, the second light-emitting diode 700, and the third light-emitting diode 800 share a common cathode conductive pad. In another embodiment, the first light-emitting diode 600, the second light-emitting diode 700, and the third light-emitting diode 800 in the pixel package body 500a share a common anode conductive pad.

The details of the second conductive structure 604CA may be referred to FIGS. 4A, 4B, 5A, 5B, 9A, 9B, 10A, 10B, 11A, 11B, 12A, and their corresponding paragraphs, and the details of the fourth conductive structure 804CA may be referred to FIGS. 11A, 11B, 12A, 12B, and their corresponding paragraphs. The subsequent paragraphs describe the overall structure of the second conductive structure 604CA and the fourth conductive structure 804CA in accordance with the diagrams and the paragraphs mentioned above.

The second conductive structure 604CA includes a conductive through hole 604V1 located in the transparent sublayer 202 (FIGS. 4A and 4B), a redistribution layer 604H1 located in the transparent sublayer 204 (FIGS. 5A and 5B), a conductive through hole 604V2 located in the transparent sublayers 204 and 206 (FIGS. 9A and 9B), a redistribution through hole 604H2 (FIGS. 10A and 10B) and a conductive through hole 604V3 (FIG. 12A) located in the transparent sublayer 208. The second conductive structure 604CA is formed in the light transparent layered structure 250, connected to the second electrode 604 (FIGS. 2A and 2B) of the first light-emitting diode 600, and to be an anode conductive structure of the first light-emitting diode 600.

The fourth conductive structure 804CA includes a redistribution layer 804H1 and a conductive through hole 804V1 located in the transparent sublayer 208. In addition, the first conductive structure 602CA, the second conductive structure 604CA, the third conductive structure 704CA, and the fourth conductive structure 804CA are separated from each other. The fourth conductive structure 804CA is formed in the transparent layered structure 250 to be the anode conductive structure of the third light-emitting diode 800.

In some embodiments, the redistribution layers 602H1, 602H2, 604H1, 604H2, 7042H1, 7042H2, and 804H1 of the first conductive structure 602CA, the second conductive structure 604CA, the third conductive structure 704CA, and the fourth conductive structure 804CA may be composed of metals (e.g., tin, gold, and copper), conductive polymer materials (e.g., conductive glue), or metal oxides (e.g., indium tin oxide (ITO), and indium zinc oxide (IZO)). The conductive through holes of the first conductive structure 602CA, the second conductive structure 604CA, the third conductive structure 704CA, and the fourth conductive structure 804CA are made of conductive metals such as gold, silver, and copper.

As shown in the FIG. 13, the structure shown in FIGS. 12A and 12B is attached to the second carrying substrate 110 through the adhesive layer 112, so that the first conductive pad 210, the second conductive pad 212, the third conductive pad 214, and the fourth conductive pad 216 are in contact with the adhesive layer 112. In some embodiments, the first carrying substrate 100 and the second carrying substrate 110 include the same or similar materials. In some embodiments, the adhesive layers 102 and 112 include the same or similar materials.

Then, the first carrying substrate 100 and the adhesive layer 102 are removed through a process, such as the LLO process. A laser light penetrates the first carrying substrate 100 and irradiates the adhesive layer 102 to separate the first carrying substrate 100 from the transparent sublayer 200. A surface 201 of the transparent sublayer 200 is exposed. In some embodiments, there is some residue of the adhesive layer 102 adhering to the surface 201 of the transparent sublayer 200, and the residual of the adhesive layer 102 may be subsequently removed by an appropriate solvent.

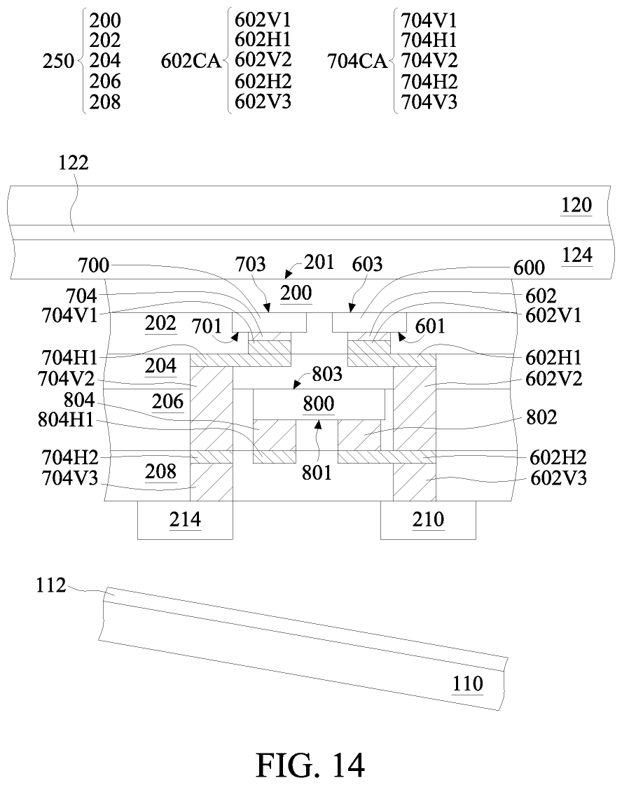

As shown in FIG. 14, the transparent sublayer 200 is then attached to the third carrying substrate 120. The third carrying substrate 120 includes an adhesive layer 122 and a carrier 124 arranged on the adhesive layer 122, and the surface 201 of the transparent sublayer 200 is in contact with the carrier 124. In some embodiments, the first carrying substrate 100, the second carrying substrate 110, and the third carrying substrate 120 include the same or similar materials. In some embodiments, adhesive layers 102, 112, 122 include the same or similar materials.

And then, the second carrying substrate 110 and the adhesive layer 112 are removed through a process, such as the LLO process. A laser light penetrates the second carrying substrate 110 and irradiates the adhesive layer 112 to separate the second carrying substrate 110 from the first conductive pad 210, the second conductive pad 212, the third conductive pad 214, and the fourth conductive pad 216, and therefore the first conductive pad 210, the second conductive pad 212, the third conductive pad 214, and the fourth conductive pad 216 are exposed. In some embodiments, there is some residue of adhesive layer 112 adhering to the surfaces of the first conductive pad 210, the second conductive pad 212, the third conductive pad 214, and the fourth conductive pad 216, and the residue of adhesive layer 112 may be subsequently removed through an appropriate solvent.

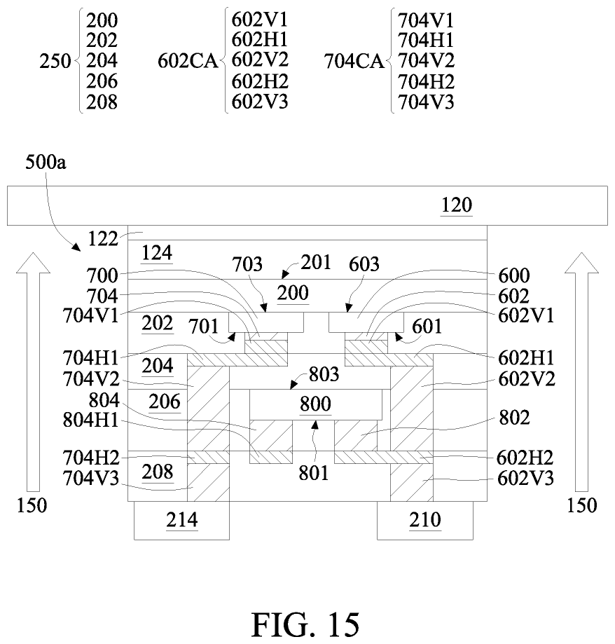

As shown in FIG. 15, a cutting process 150 is carried out to the carrier 124 and the transparent layered structure 250 in order to form multiple separated pixel packages 500a. Although the structure of a single pixel package is shown in the aforementioned drawings, in the actual manufacturing processes, multiple identical pixel packages may be made simultaneously on a same carrying substrate so that the transparent layered structure 250, the adhesive layer 102, and the first carrying substrate 100 in FIGS. 2A, 2B to 12A, and 12B; the transparent layered structure 250, the adhesive layers 102 and 112, the first carrying substrate 100, and the second carrying substrate 110 in FIG. 13; and the transparent layered structure 250, the adhesive layers 112 and 122, the second carrying substrate 110, and the third carrying substrate 120 in FIG. 14 may be the connection structure connecting multiple identical pixel packages, and then each pixel package is separated by the cutting process shown in this figure so that the continuous structures shown in FIGS. 2B-12B, FIG. 13, and FIG. 14 are all illustrated with wavy shaped sidewalls.

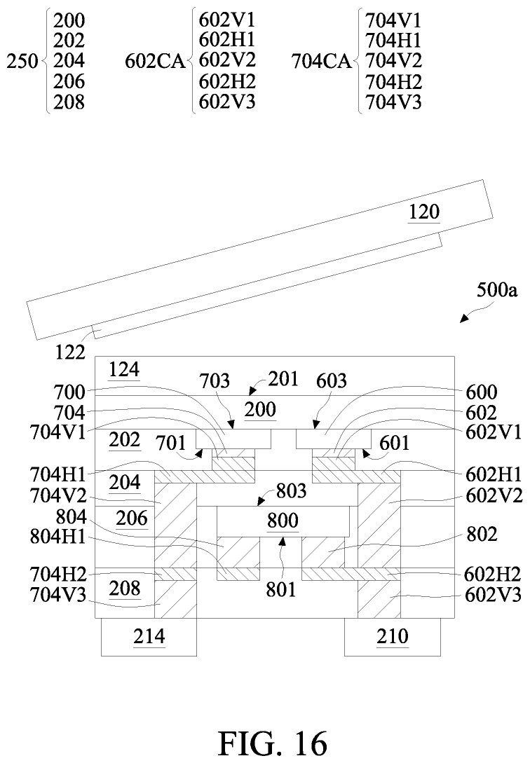

Finally, as shown in FIG. 16, the LLO process may be carried out to use a laser light to penetrate the third carrier substrate 120 and to irradiate the adhesive layer 122 to separate the third carrier substrate 120 and the adhesive layer 122 from the pixel package body 500a.

The pixel package shown in the embodiments of the present disclosure is formed by vertically stacking light-emitting diodes in a flip mode to effectively reduce the volume of the pixel package. In addition, the photoimageable dielectric material (PID) used as the carrying substrate, the electrical insulating layer, and the dielectric interlayer of the pixel package in the embodiment of the present disclosure has the advantages of high chemical resistance, flat surface, and high light transmittance so that the mechanical strength of the pixel package may be improved while keeping the high transmittance and the conductive structure manufacturing process therein is easy to carry out. Because the photosensitive dielectric material may provide good support for the vertically stacked light-emitting diodes, it may carry the larger red light-emitting diodes by increasing the light output area to uniformly produce light in all colors of the pixel package. In addition, due to the height difference formed by vertically stacked light-emitting diodes, the pixel package has deep conductive through holes. In some embodiments, nano conductive glue material may be chosen as a filling material for the conductive through holes. Compared with the traditional process, the conductive through hole filling process in the embodiment of the present disclosure does not require additional planarization processes such as chemical mechanical grinding, which may reduce the process cost.

Although some embodiments of the present disclosure and their advantages have been described in detail, various changes, substitutions and alterations may be made herein without departing from the spirit and scope of the disclosure as defined by the appended claims.

What is claimed is:

1. A pixel package, comprising:
a first light-emitting diode;
a second light-emitting diode;
a third light-emitting diode, comprising a first light-emitting surface and a first bottom surface opposite to the first light-emitting surface, and the first light-emitting diode arranged side by side with the second light-emitting diode over the first light-emitting surface;
a transparent layered structure, encapsulating and separating the first light-emitting diode, the second light-emitting diode, and the third light-emitting diode; and
a first conductive structure, comprising a first portion and a second portion, the first portion located between the first light-emitting diode and the first light-emitting surface, and the second portion located under the first portion and exposed from the transparent layered structure;
wherein, in a plan view, the third light-emitting diode is respectively overlapped with the first light-emitting diode and the second light-emitting diode.

2. The pixel package according to claim 1, wherein the first conductive structure is connected to a first electrode of the first light-emitting diode, a second electrode of the second light-emitting diode, and a first electrode of the third light-emitting diode.

3. The pixel package according to claim 2, further comprising:
a second conductive structure connected to a second electrode of the first light-emitting diode;
a third conductive structure, located between the second light-emitting diode and the first light-emitting surface, and connected to the second electrode of the second light-emitting diode; and
a fourth conductive structure, located under the first bottom surface, and connected to a second electrode of the third light-emitting diode;
wherein the first conductive structure, the second conductive structure, the third conductive structure, and the fourth conductive structure are separated from each other.

4. The pixel package according to claim 3, wherein the first light-emitting diode comprises a second light-emitting surface and a second bottom surface, the second light-emitting diode comprises a third light-emitting surface and a third bottom surface, and the second light-emitting surface and the third light-emitting surface are respectively opposite to the second bottom surface and the third bottom surface.

5. The pixel package according to claim 4, wherein the first light-emitting surface faces to the second bottom surface and the third bottom surface.

6. The pixel package according to claim 5, further comprising a carrier located on the transparent layered structure, the first light-emitting surface, the second light-emitting surface, and the third light-emitting surface.

7. The pixel package according to claim 1, wherein the first light-emitting diode, the second light-emitting diode, and the third light-emitting diode emit different dominant wavelengths.

8. The pixel package according to claim 7, wherein the first light-emitting diode emits a blue light, the second light-emitting diode emits a green light, and the third light-emitting diode emits a red light.

9. The pixel package according to claim 1, wherein, in a plane view, the third light-emitting diode comprises a first long side extending along a first direction, the first light-emitting diode comprises a second long side extending along a second direction, the second light-emitting diode comprises a third long side extending along a third direction, and the first direction is different from the second direction.

10. The pixel package according to claim 9, wherein the first long side is substantially perpendicular to the second long side.

11. The pixel package according to claim 10, wherein the second long side and the third long side are extending substantially along a same direction.

12. The pixel package according to claim 4, wherein the first light-emitting surface has a first surface area, the second light-emitting surface has a second surface area, the third light-emitting surface has a third surface area, and the first surface area is larger than the second surface area.

13. The pixel package according to claim 12, wherein the second surface area and the third surface area are substantially the same.

14. The pixel package according to claim 1, wherein the transparent layered structure is composed of a photoimageable dielectric material.

15. The pixel package according to claim 6, wherein the carrier is composed of an organic polymer material and comprises different composition from the transparent layered structure.

16. The pixel package according to claim 15, wherein the carrier comprises a hardness larger than that of the transparent layered structure.

17. The pixel package according to claim 1, further comprising a first conductive pad, a second conductive pad, a third conductive pad, and a fourth conductive pad electrically connected to the first light-emitting diode, the second light-emitting diode, the third light-emitting diode, and wherein one of the first conductive pad, a second conductive pad, a third conductive pad, and a fourth conductive pad comprises a shape different from the other conductive pads.

18. The pixel package according to claim 17, wherein the first conductive pad is connected to the first conductive structure, the second conductive pad is connected to the second conductive structure, the third conductive pad is connected to the third conductive structure, and the fourth conductive pad is connected to the fourth conductive structure, and one of the first conductive pad, a second conductive pad, a third conductive pad, and a fourth conductive pad comprises a polarity different from the other conductive pads.

19. The pixel package according to claim 1, wherein the first portion and the second portion are extending along different directions.

20. The pixel package according to claim 1, wherein pixel package comprises a planar light-emitting surface.
